(19) United States
(12) Patent Application Publication
(10) Pub. No.: US 2018/0323277 A1
(43) Pub. Date: Nov. 8, 2018

(54) FIN-FET DEVICES AND FABRICATION METHODS THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Fei ZHOU, Shanghai (CN)

(21) Appl. No.: 15/971,109

(22) Filed: May 4, 2018

(30) Foreign Application Priority Data
May 5, 2017 (CN) 201710311016.8

(51) Int. Cl. H01L 29/66; H01L 29/78; H01L 29/417; H01L 21/8234; H01L 21/762

(52) U.S. Cl. CPC H01L 29/6681; H01L 29/785; H01L 21/762; H01L 21/823431; H01L 29/41791

(57) ABSTRACT

A method for fabricating a Fin-FET device includes forming a plurality of discrete fin structures on a substrate which includes a first device region and a second device region, forming a plurality of dummy gate electrodes across the fin structures, and forming an interlayer dielectric layer exposing the dummy gate electrodes on a portion of the fin structures exposed by the dummy gate electrodes, forming a first opening by removing each dummy gate electrode, forming an initial metal gate electrode in the first opening and between adjacent fin structures, and forming a second opening through the initial metal gate electrode. The initial metal gate electrode formed in the first device region is a first metal gate electrode, and the initial metal gate electrode formed in the second device region is a second metal gate electrode. The second opening separates the first metal gate electrode from the second metal gate electrode.

### CROSS-REFERENCES TO RELATED APPLICATIONS

This application claims the priority of Chinese Patent Application No. CN201710311016.8, filed on May 5, 2017, the entire content of which is incorporated herein by reference.

### FIELD OF THE DISCLOSURE

The present disclosure generally relates to the field of semiconductor fabrication technology and, more particularly, relates to fin field-effect transistor (Fin-FET) devices and fabrication methods thereof.

### BACKGROUND

With the rapid development of semiconductor technology, the feature size of semiconductor structures is continuously reduced, and the integration level of integrated circuits (ICs) becomes higher and higher. Accordingly, requirements on the performance of the devices may also be higher.

Currently, with the dimension of metal-oxide-semiconductor field-effect transistor (MOSFET) continuously becoming smaller, the channel length in MOSFET devices may have to be reduced in order to accommodate the reduction of the process node. The reduction of the channel length may be conducive to increasing the density of the transistors in the chip, improving the switching speed of the MOSFET devices, etc.

However, as the channel length of devices decreases, the distance between the source region and the drain region may also be reduced. As a result, the ability of the gate structure in controlling the channel may be degraded, and thus pinching off the channel by the gate may be more difficult. Therefore, the sub-threshold leakage phenomenon, i.e. the short-channel effect (SCE), becomes a crucial technical challenge and needs to be solved.

In order to accommodate the requirements for scaling-down semiconductor devices, semiconductor process gradually switches from planar MOSFET devices to more efficient three-dimensional (3D) transistor devices, such as fin field-effect transistor (Fin-FET) devices, with desired ability in controlling the channels.

However, the electrical performance of the conventional semiconductor structures may still need to be improved. The disclosed Fin-FET devices and fabrication methods thereof are directed to solve one or more problems set forth above and other problems in the art.

### BRIEF SUMMARY OF THE DISCLOSURE

One aspect of the present disclosure provides a method for fabricating a Fin-FET device. The method includes forming a plurality of discrete fin structures on a substrate. The substrate includes a first device region and a second device region. The method also includes forming a plurality of dummy gate electrodes across the fin structures to cover a portion of top and sidewall surfaces of each fin structure, and forming an interlayer dielectric layer on a portion of the fin structures exposed by the dummy gate electrodes. The interlayer dielectric layer exposes the dummy gate electrodes. The method further includes forming a first opening in the interlayer dielectric layer by removing each dummy gate electrode, forming an initial metal gate electrode to fill up the first opening and on the substrate between adjacent fin structures, and forming a second opening through the initial metal gate electrode and on the substrate. A portion of the initial metal gate electrode formed in the first device region is a first metal gate electrode, and a portion of the initial metal gate electrode formed in the second device region is a second metal gate electrode. The second opening separates the first metal gate electrode in the first device region from the second metal gate electrode in the second device region.

Another aspect of the present disclosure provides a Fin-FET device. The Fin-FET device includes a substrate including a first device region and a second device region, a plurality of discrete fin structures formed on the substrate, an initial metal gate electrode formed across the plurality of fin structure and covering a portion of top and sidewall surfaces of each fin structure in the first and second device regions, and an interlayer dielectric layer formed on a portion of the fin structures exposed by the initial metal gate electrode. The initial metal gate electrode contains an opening between adjacent fin structures in the first and second device regions.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-23 illustrate schematic views of semiconductor structures at certain stages when fabricating a Fin-FET device consistent with various embodiments of the present disclosure; and

FIG. 24 illustrates a flowchart of the exemplary method for fabricating a Fin-FET device consistent with various embodiments of the present disclosure.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

A Fin-FET device may be formed by first providing a substrate. The substrate includes a first device region and a second device region. A plurality of discrete fin structures are formed on the substrate. The fabrication method also includes forming a plurality of dummy gate electrodes across the plurality of fin structures, and forming an interlayer dielectric layer on a portion of each fin structure exposed by the dummy gate electrode. The interlayer dielectric layer exposes the dummy gate electrode. That is, the interlayer dielectric layer does not cover the dummy gate electrode. Further, the fabrication method includes performing a patterning process on the dummy gate electrodes to remove each dummy gate electrode and form a first opening in the interlayer dielectric layer. Along a direction perpendicular to the surface of the substrate, the first opening is formed through the dummy gate electrode. Moreover, the fabrication method includes forming a dielectric layer to fill the first opening, and removing the remaining portion of the dummy gate structure to form a second opening and a third opening in the interlayer dielectric layer. The dielectric layer formed to fill the first opening separates the second opening and the third opening. The fabrication method further includes forming a first metal gate electrode to fill the second opening, and forming a second metal gate electrode to fill the third opening.

The electrical performance of the formed Fin-FET device may not be desired due to several reasons. According to the fabrication method, alter forming the interlayer dielectric layer, the dummy gate structure is patterned to form a first opening in the interlayer dielectric layer; and after forming the first opening, the first metal gate electrode and the second metal gate electrode are then formed. That is, the first metal gate electrode and the second metal gate electrode are formed after forming the first opening. Therefore, after removing the remaining portion of each dummy gate electrode to form the second opening and the third opening, the distance from the sidewall surfaces of the second opening and the third opening to the adjacent fin structures is relatively small. That is, the aspect ratio of the second opening and the aspect ratio of the third opening are relatively small. As a result, it is not easy to fill up the second opening and the third opening. In a subsequent process to fill a metal material into the second opening and the third opening, because it is not easy to fill up the second opening and the third opening, the filling process may become difficult. Therefore, the metal material may not sufficiently fill the second opening and the third opening, which may easily cause the formation of gaps or pin-holes. As such, the quality of the first metal gate electrode and the second metal gate electrode may be poor, and thus the electrical performance of the formed Fin-FET device may need to be improved.

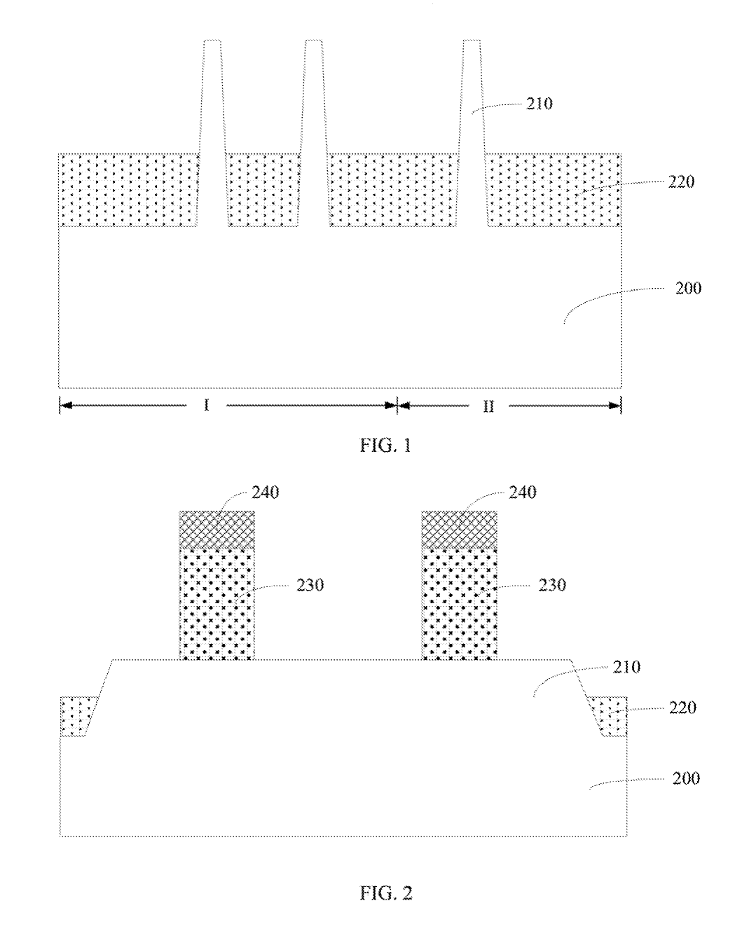

The present disclosure provides a method for fabricating Fin-FET devices to improve the electrical performance of the formed Fin-FET devices. FIG. 24 illustrates a flowchart of the exemplary method for fabricating a semiconductor structure consistent with various embodiments of the present disclosure. FIGS. 1-23 illustrate schematic views of semiconductor structures at certain stages of the exemplary fabrication method.

Referring to FIG. 24, at the beginning of the fabrication process, a substrate including a first device region and a second device region may be provided, and a plurality of discrete fin structures and an isolation structure may be formed on the substrate (S401). FIG. 1 illustrates a schematic cross-section view of a semiconductor structure consistent with some embodiments of the present disclosure. Specifically, the schematic cross-section view shown in FIG. 1 is along the extending direction of a fin structure 210.

Referring to FIG. 1, a substrate 200 may be provided. The substrate 200 may include a first device region I and a second device region II. Moreover, a plurality of discrete fin structures 210 may he formed on the substrate 200, and an isolation structure 220 may also be formed on the substrate 200.

In one embodiment, the substrate 200 is made of silicon. In other embodiments, the substrate may be made of germanium, SiGe, SiC, GaAs, InAs, or any other appropriate semiconductor material. Alternatively, the substrate may be made of silicon on insulator (SOI), germanium on insulator (GOI), or any other composite semiconductor structure.

In one embodiment, the plurality of fin structures 210 are made of silicon. In other embodiments, the plurality of fin structures may be made of germanium, SiGe, SiC, GaAs, InAs, or any other appropriate semiconductor material.

In one embodiment, the isolation structure 220 may be used to isolate adjacent fin structures 210. The isolation structure 220 maybe made of SiOₓ, SiNₓ, or SiON.

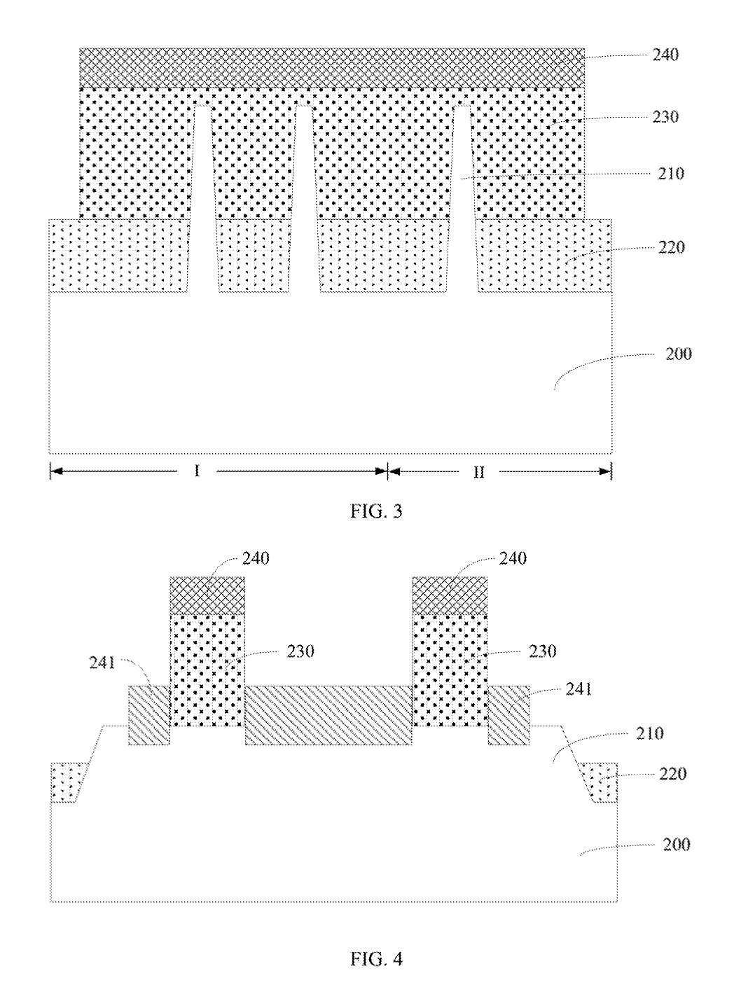

Further, returning to FIG. 24, a plurality of dummy gate electrodes may be formed across the plurality of fin structures to cover a portion of the sidewall and the top surfaces of each fin structure, and a hard mask layer may be formed on the plurality of dummy gate electrodes (S402). FIGS. 2-3 show schematic cross-section views of a semiconductor structure consistent with some embodiments of the present disclosure. Specifically, FIG. 2 shows a schematic cross-section view of the semiconductor structure along the extending direction of a fin structure 210, and FIG. 3 shows a schematic cross-section view of the semiconductor structure along the direction perpendicular to the extending direction of the fin structure 210.

Referring to FIGS. 2-3, a plurality of dummy gate electrodes 230 may be formed across the plurality of fin structures 210. Each dummy gate electrode 230 may cover a portion of the sidewall and the top surfaces of each fin structure 210. Moreover, a hard mask layer 240 may be formed on the plurality of dummy gate electrodes 230.

In one embodiment, the plurality of dummy gate electrodes 230 may be made of polycrystalline silicon. The plurality of dummy gate electrodes 230 may be formed through a process including the following steps. First, a dummy gate film may be formed across the plurality of fin structures 210. The hard mask layer 240 may then be formed on the dummy gate film. The hard mask layer 240 may define the positions and the dimensions of the dummy gate electrodes. Further, the plurality of dummy gate electrodes 230 may be formed by etching the dummy gate film using the hard mask layer 240 as an etch mask. In one embodiment, after forming the plurality of the dummy gate electrodes 230, the hard mask layer 240 may be retained. The hard mask foyer 240 may be used to protect the top surfaces of the plurality of dummy gate electrodes 230 in a subsequent process. In other embodiments, the hard mask layer may be removed after forming the plurality of dummy gate electrodes.

Further, returning to FIG. 24, a plurality of source/drain doped regions may be formed in the fin structures on both sides of each dummy gate electrode (S403). FIG. 4 illustrates a schematic cross-section view of a semiconductor structure consistent with some embodiments of the present disclosure. Specifically, the cross-section view shown in FIG. 4 is along the extending direction of a fin structure 210 of the semiconductor structure.

Referring to FIG. 4, a plurality of source/drain, doped regions 241 may be formed in the fin structures 210 on the two opposite sides of each dummy gate electrode 230.

In one embodiments, the source/drain doped regions may be made of silicon, SIC, SiGe, or any other appropriate material. For example, the material used to for the source/drain doped regions 241 in the first device region I and the second region II may be selected based on the types of the devices to be formed in the first device region I and the second region II, respectively.

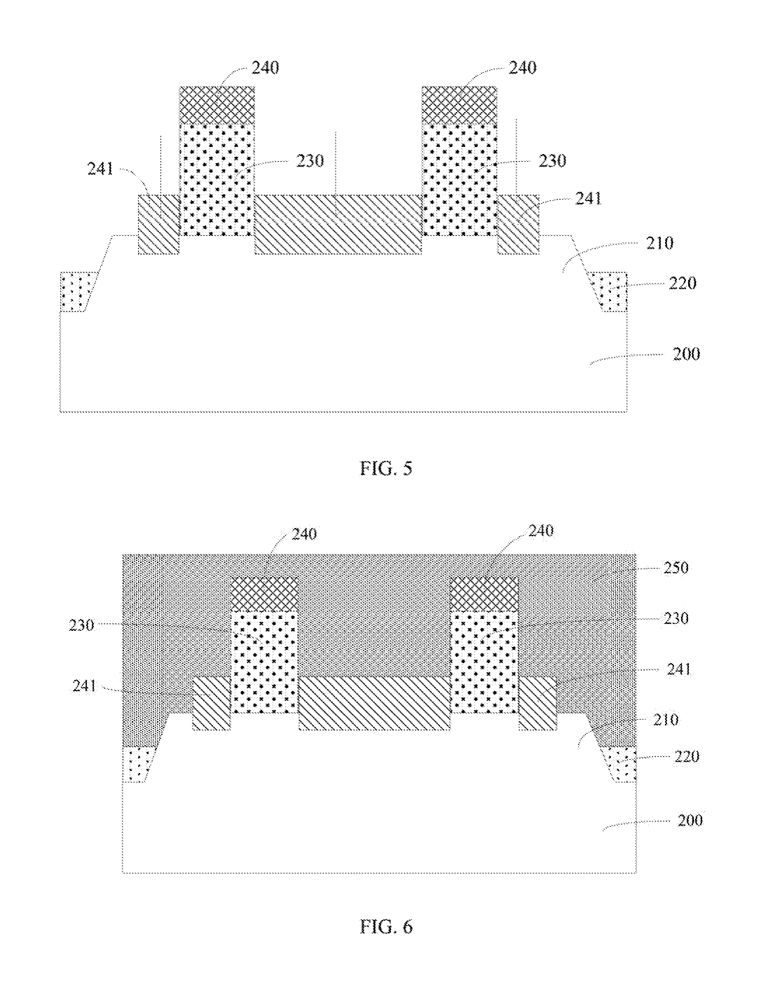

Further, returning to FIG. 24, the plurality of source/drain doped regions may be implanted with doping ions (S404). FIG. 5 illustrates a schematic cross-section view of a semiconductor structure consistent with some embodiments of the present disclosure. Specifically, the cross-section view shown in FIG. 5 is along the extending direction of a fin structure 210 of the semiconductor structure.

Referring to FIG. 5, doping ions may be implanted into the plurality of source/drain doped regions 241. In one embodiment, implanting doping ions into the plurality of source/drain doped regions 241 may be aimed to reduce the contact resistance of the source/drain doped regions 241. The types of the doping ions used in the ion implantation process may be selected based on the types of the devices to be subsequently-formed in the first device region I and/or the second device region II.

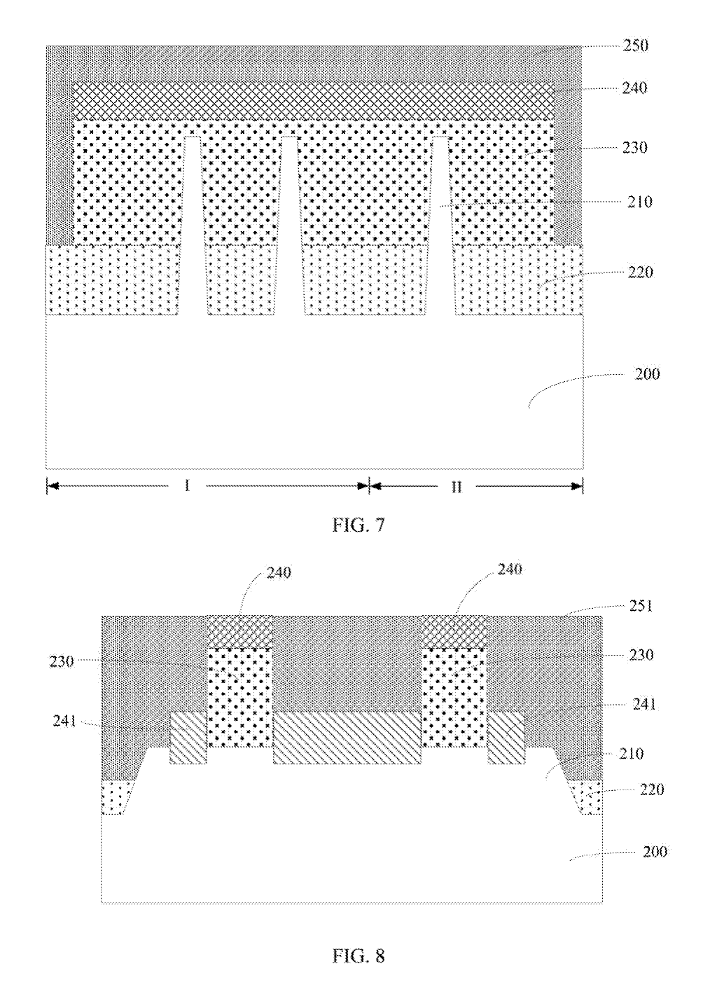

Further, returning to FIG. 24, an interlayer dielectric film may be formed on the portion of the substrate exposed between neighboring fin structures with the top surface of the interlayer dielectric film higher than the top surface of the hard mask layer (S405). FIGS. 6-7 show schematic cross-section views of a semiconductor structure consistent with some embodiments of the present disclosure. Specifically, FIG. 6 shows a schematic cross-section view of the semiconductor structure along the extending direction of a fin structure 210, and FIG. 7 shows a schematic cross-section view of the semiconductor structure along the direction perpendicular to the extending direction of the fin structure 210.

Referring to FIGS. 6-7, an interlayer dielectric film 250 may be formed on the portion of the substrate 200 exposed between neighboring fin structures 210. The top surface of the interlayer dielectric film 250 may be higher than the top surface of the hard mask layer 240. That is, the interlayer dielectric film 250 may cover the top surface of the hard mask layer 240.

In one embodiment, the interlayer dielectric film 250 is made of SiOₓ. In other embodiments, the interlayer dielectric film may be made of one or more of SiNₓ, SiON, etc.

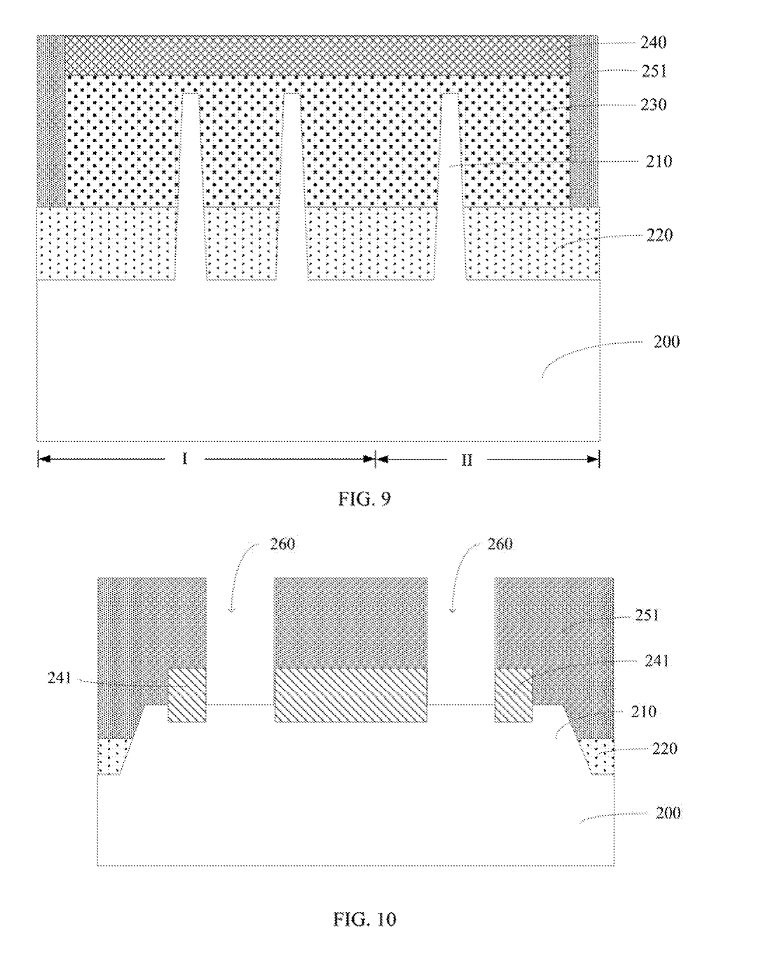

Further, returning to FIG. 24, the interlayer dielectric film may be planarized to form an interlayer dielectric layer exposing the hard mask layer (S406). FIGS. 8-9 show schematic cross-section views of a semiconductor structure consistent with some embodiments of the present disclosure. Specifically, FIG. 8 shows a schematic cross-section view of the semiconductor structure along the extending direction of a fin structure 210, and FIG. 9 shows a schematic cross-section view of the semiconductor structure along the direction perpendicular to the extending direction of the fin structure 210.

Referring to FIGS. 8-9, the interlayer dielectric film 250 (referring to FIG. 7) may be planarized to form an interlayer dielectric layer 251. The interlayer dielectric layer 251 may expose the hard mask layer 240.

In one embodiment, the interlayer dielectric layer 251 is formed by planarizing the interlayer dielectric film 250, and accordingly, the inter layer dielectric layer 251 is also made of SiOₓ. In other embodiments, the interlayer dielectric layer may be made of one or more of SiNₓ, SiON, etc.

In one embodiment, the interlayer dielectric film 250 may be planarized by a chemical mechanical polishing (CMP) process. As such, the interlayer dielectric film 250 may be globally planarized such that the top surface of the formed interlayer dielectric layer 251 may have desired flatness after the CMP process. Therefore, the quality of the interlayer dielectric layer 251 may be improved.

Further, returning to FIG. 24, the plurality of dummy gate electrodes and the hard mask layer formed on the dummy gate electrodes may be removed to form a first opening in the interlayer dielectric layer (S407). FIGS. 10-11 show schematic cross-section views of a semiconductor structure consistent with some embodiments of the present disclosure. Specifically, FIG. 10 shows a schematic cross-section view of the semiconductor structure along the extending direction of a fin structure 210, and FIG. 11 shows a schematic cross-section view of the semiconductor structure along the direction perpendicular to the extending direction of the fin structure 210.

Referring to FIGS. 10-11, each dummy gate electrode 230 (referring to FIG. 8 and FIG. 9) and the hard mask layer 240 (referring to FIG. 8 and FIG. 9) formed on the dummy gate electrode 230 may be removed to form a first opening 260 in the interlayer dielectric layer 251.

In one embodiment, the dummy gate electrode 230 and the hard mask layer 240 may be removed by a dry etching process. In a subsequent process, the first opening 260 may be filled up to farm an initial metal gate electrode. Because the distance from the sidewall surface of the first opening 260 to the fin structures 210 is relatively large, the first opening 260 may have a relatively large aspect ratio. Therefore, the first opening may be easily filled up in the filling process. Further, because filling the first opening becomes relatively easy, the quality of the subsequently-formed initial metal gate electrode may he improved.

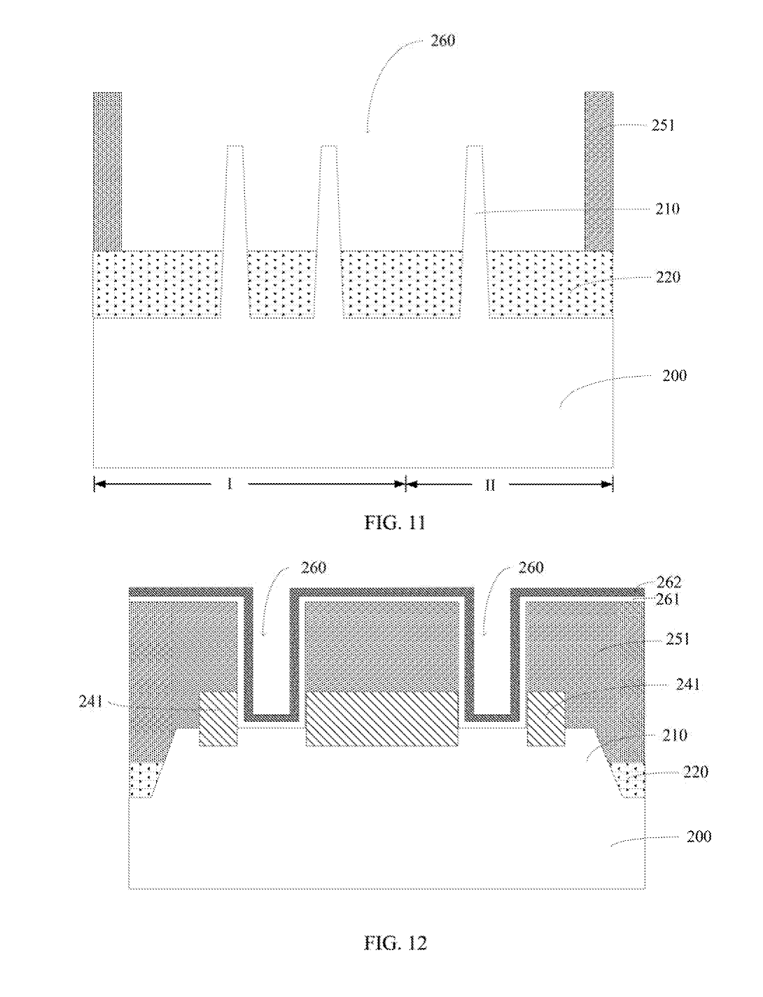

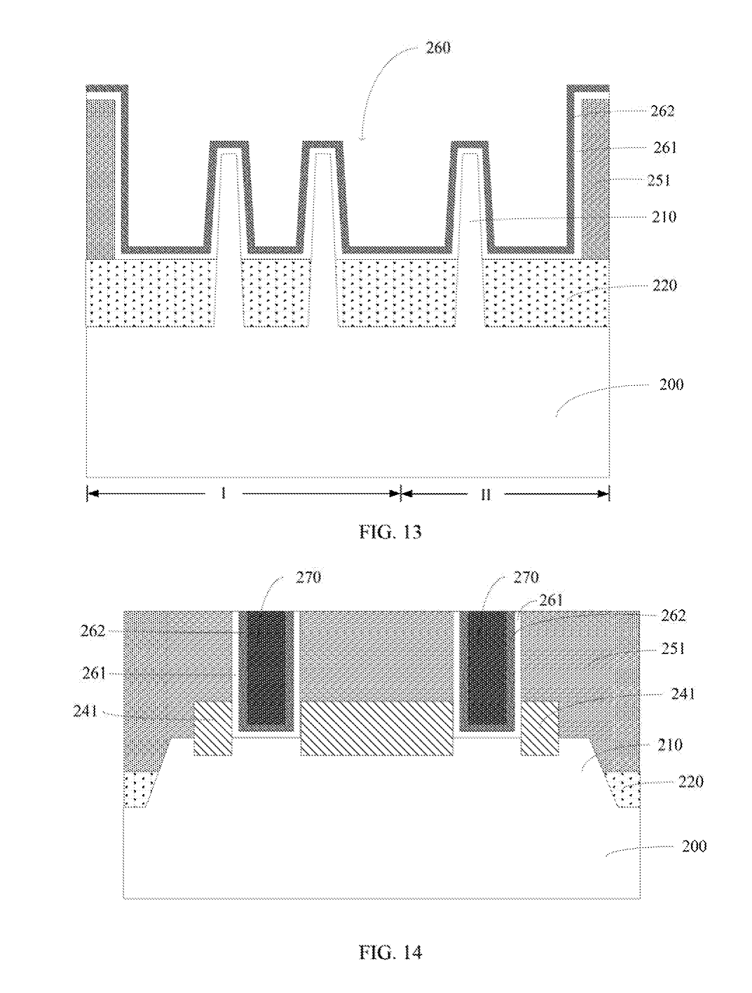

Further, returning to FIG. 24, a high-k dielectric layer may be formed on the interlayer dielectric layer as well as the bottom and the sidewall surfaces of the first opening, a work function layer may then be formed on the high-k dielectric layer (S408). FIGS. 12-13 show schematic cross-section views of a semiconductor structure consistent with some embodiments of the present disclosure. Specifically, FIG. 12 shows a schematic cross-section view of the semiconductor structure along the extending direction of a fin structure 210, and FIG. 13 shows a schematic cross-section view of the semiconductor structure along the direction perpendicular to the extending direction of the fin structure 210.

Referring to FIGS. 12-13, a high-k dielectric layer 261 may be formed on the interlayer dielectric layer 251 and also on the bottom and the sidewall surfaces of the first opening 260. Moreover, a work function layer 262 may then be formed on the high-k dielectric layer 261.

In one embodiment, the high-k dielectric layer 261 may be used to isolate the metal gate electrode and the channel of the Fin-FET device. The high-k dielectric layer 261 may be made of one or more of HfOₓ, LaHfOₓ, etc.

In one embodiment, the work function layer 262 may be used to adjust the threshold voltage of the subsequently-formed Fin-FET device. The work function layer 262 may be made of one or more of TiNₓ, TaNₓ, etc.

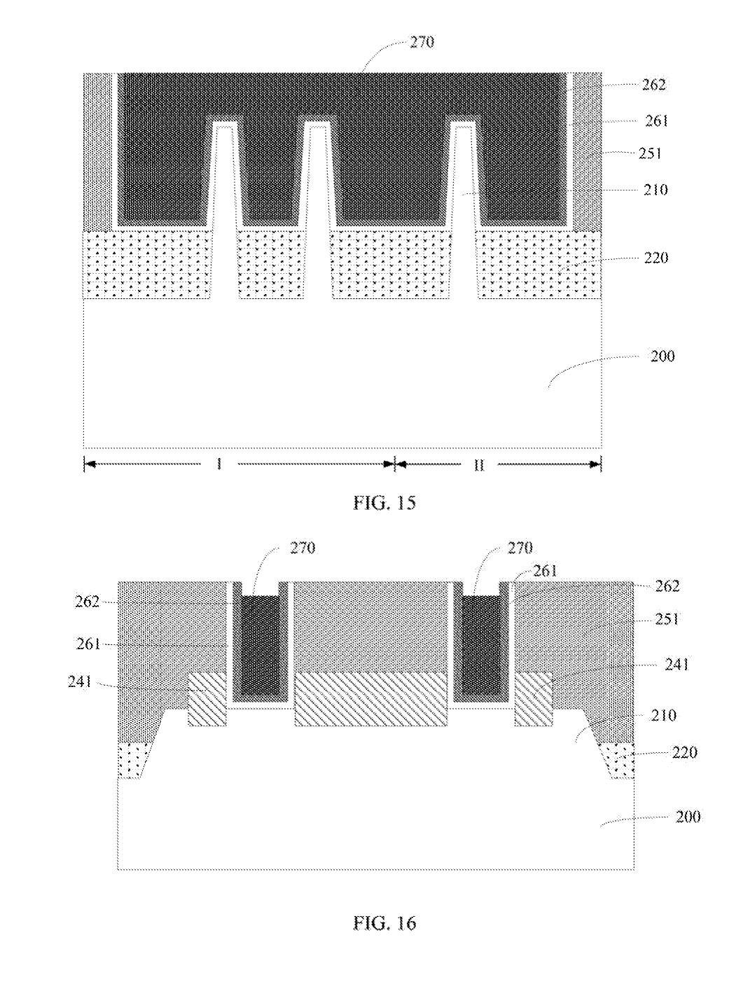

Further, returning to FIG. 24, each first opening may be filled up to form an initial metal gate electrode (S409). FIGS. 14-15 show schematic cross-section views of a semiconductor structure consistent with some embodiments of tire present disclosure. Specifically, FIG. 14 shows a schematic cross-section view of the semiconductor structure along the extending direction of a fin structure 210, and FIG. 15 shows a schematic cross-section view of the semiconductor structure along the direction perpendicular to the extending direction of the fin structure 210.

Referring to FIGS. 14-15, each first opening 260 (referring to FIG. 12 and FIG. 13) may be filled up to form an initial metal gate electrode 270.

In one embodiment, the first opening 260 may be easily filled up such that the quality of the formed initial metal gate electrode 270 may be improved. The initial metal gate electrode 270 may be made of one or more of Ti, Ta, TiNₓ, TaNₓ, AlTiₓ, AlTiNₓ, Cu, Al, W, Ag, Au, and any other appropriate material.

In one embodiment, the initial metal gate electrode 270 may be formed by a process including the following steps. An initial metal gate film may be formed to fill up the first opening 260. The top surface of the initial metal gate film may be higher than the top surface of the interlayer dielectric layer 251. An planarization process may be performed on the initial metal gate film to remove the portion of the initial metal gate film formed above the top surface of the interlayer dielectric layer 251 and also remove the portion of the high-k dielectric layer 261 and the work function layer 262 formed on the top surface of the interlayer dielectric layer 251. As such, the initial metal gate electrode 270 may be formed.

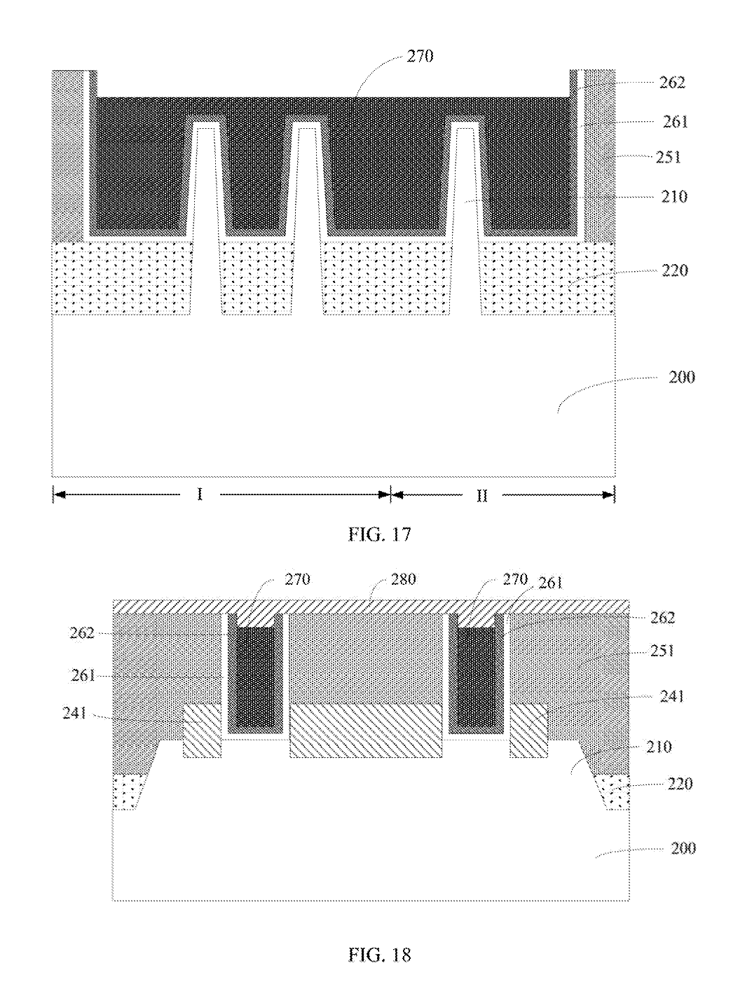

Returning to FIG. 24, a top portion of the initial metal gate electrode may be removed (S410). FIGS. 16-17 show schematic cross-section views of a semiconductor structure consistent with some embodiments of the present disclosure. Specifically, FIG. 16 shows a schematic cross-section view of the semiconductor structure along the extending direction of a fin structure 210, and FIG. 17 shows a schematic cross-section view of the semiconductor structure along the direction perpendicular to the extending direction of the fin structure 210.

Referring to FIGS. 16-17, a top portion of the initial metal gate electrode 270 may be removed. In one embodiment, the top portion of the initial metal gate electrode 270 may be removed by a dry etching process. The removal of the top portion of the initial metal gate electrode 270 may be aimed to provide a space for a cap layer subsequently formed on the top of the initial metal gate electrode 270.

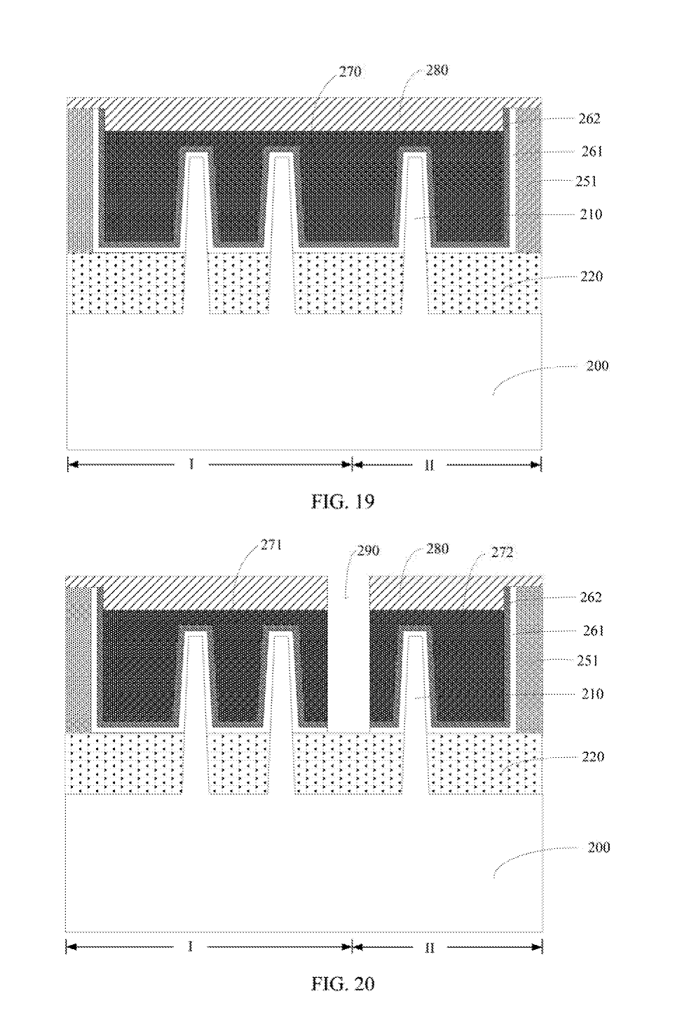

Further, returning to FIG. 24, a cap layer may be formed on the initial metal gate electrode and the interlayer dielectric layer with the top surface of the cap layer higher than the top surface of the interlayer dielectric layer (S411). FIGS. 18-19 show schematic cross-section views of a semiconductor structure consistent with some embodiments of the present disclosure. Specifically, FIG. 18 shows a schematic cross-section view of the semiconductor structure along the extending direction of a fin structure 210, and FIG. 19 shows a schematic cross-section view of the semiconductor structure along the direction perpendicular to the extending direction of the fin structure 210.

Referring to FIGS. 18-19, a cap layer 280 may be formed on the initial metal gate electrode 270 and the interlayer dielectric layer 251. The top surface of cap layer 280 may be higher than the top surface of the interlayer dielectric layer 251.

In one embodiment, the cap layer 280 may provide protection for the top of the initial meatal gate electrode 271. The cap layer 280 may be made of one or more of SiNₓ, SiCN, SiBN, SiCON, SiCN, and amorphous carbon.

Further, returning to FIG. 24, the initial metal gate electrode may be patterned to form a second opening penetrating through the initial metal gate electrode at the boundary between the first device region and the second device region, and accordingly, the portion of the initial metal gate electrode in the first device region may become a first metal gate electrode and the portion of the initial metal gate electrode in the second device region may become a second metal gate electrode (S412). FIG. 20 illustrates a schematic cross-section view of a semiconductor structure consistent with some embodiments of the present disclosure along a direction perpendicular to the extending direction of the fin structures 210.

Referring to FIG. 20, a second opening 290 may be formed by patterning the initial gate electrode 270 (referring to FIG. 18 and FIG. 19). The second opening 290 may be formed through the entire thickness of the initial gate electrode 270 at the boundary between the first device region I and the second device region II. The portion of the initial metal gate electrode 270 formed in the first device region I may become a first metal gate electrode 271, and the portion of the initial metal gate electrode 270 formed in the second device region II may become a second metal gate electrode 272. Therefore, the second opening 290 may be formed between the first metal gate electrode 271 and the second metal gate electrode 272.

In one embodiment, the second opening 290 may be formed through the work function layer 262 and the high-k dielectric layer 261 to divide the work function layer 262 and the high-k dielectric layer 261 into two parts, corresponding to the first device region I and the second device region II, respectively.

In one embodiment, the second opening 290 may be used to break the connection between the first metal gate electrode 271 and the second metal gate electrode 272. The second opening 290 may be formed after forming the initial metal gate electrode 270. Because the quality of the initial metal gate electrode 270 maybe improved, the quality of the first metal gate electrode 271 and the second metal gate electrode 272 may also be improved. As such, the electrical performance of the Fin-FET device may be improved.

In one embodiment, along the direction perpendicular to the extending direction of the fin structure 210, the width of the second opening 290 may not be too large or too small. When the width of the second opening 290 is too large, the semiconductor process materials may be wasted. When the width of the second opening 290 is too small, the semiconductor fabrication process may be more difficult, and the connection between the first metal gate electrode 271 and the second metal gate electrode 272 may not be completely cut off. Therefore, along the direction perpendicular to the extending direction of the fin structure 210, the width of the second opening may be in a range of approximately 50 Å to 100 Å.

In one embodiment, the second opening 290 may be formed by a dry etching process. The parameters used in the dry etching process may include an etching gas containing a mixture of CF₄, SF₆, Cl₂, and O₂, a flowrate of CF₄ in a range of approximately 10 seem to 500 seem, a flowrate of SF₆ in a range of approximately 20 sccm and 300 sccm, a flowrate of Cl₂ in a range of approximately 6 sccm to 120 sccm, a fiowrate of O₂ in a range of approximately 1 sccm to 90 sccm, a process pressure in a range of approximately 1 mTorr to 350 mTorr, and a process power in a range of approximately 100 W to 500 W.

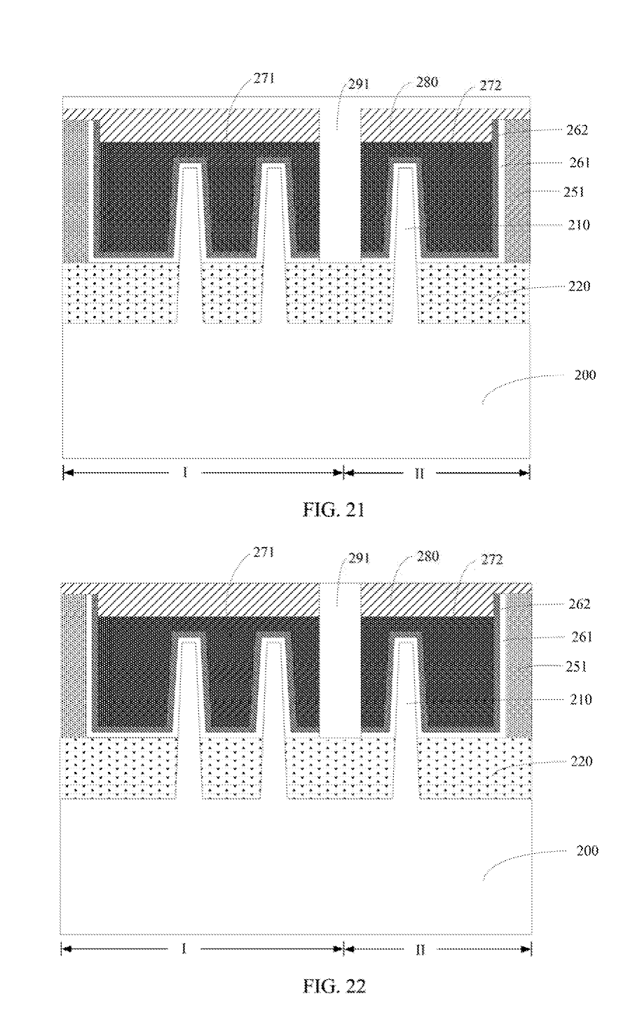

Further, returning to FIG. 24, a dielectric film may be formed on the bottom and the sidewall surfaces of the second opening and also on the cap layer (S413). FIG. 21 illustrates a schematic cross-section view of a semiconductor structure consistent with some embodiments of the present disclosure along a direction perpendicular to the extending direction of the fin structure 210.

Referring to FIG. 21, a dielectric film 291 may be formed on the bottom and the sidewall surfaces of the second opening 290. The dielectric film 291 may also be formed on the top of the cap layer 280.

In one embodiment, the dielectric film 291 may be formed by a fluid chemical vapor deposition (CVD) process. In other embodiments, the dielectric film may be formed by an atomic layer deposition (ALD) process, or any other appropriate deposition process.

In one embodiment, the dielectric film 291 may be made of a low-k dielectric material. The low-k dielectric material may refer to a material with a dielectric constant lower than 3.9. For example, the low-k dielectric material may be one or more of SiOₓ, SiON, and SiCO.

Further, returning to FIG. 24, a first planarization process using the cap layer as a process stop layer may be performed on the dielectric film to remove the portion of the dielectric film formed above the top surface of the cap layer (S414). FIG. 22 illustrates a schematic cross-section view of a semiconductor structure consistent with some embodiments of the present disclosure along a direction perpendicular to the extending direction of the fin structure 210.

Referring to FIG. 22, a first planarization process using the cap layer 280 as a process stop layer may be performed on the dielectric film 291 to remove the portion of the dielectric film 291 formed above the top surface of the cap layer 280. In one embodiment, the first planarization process may be a CMP process.

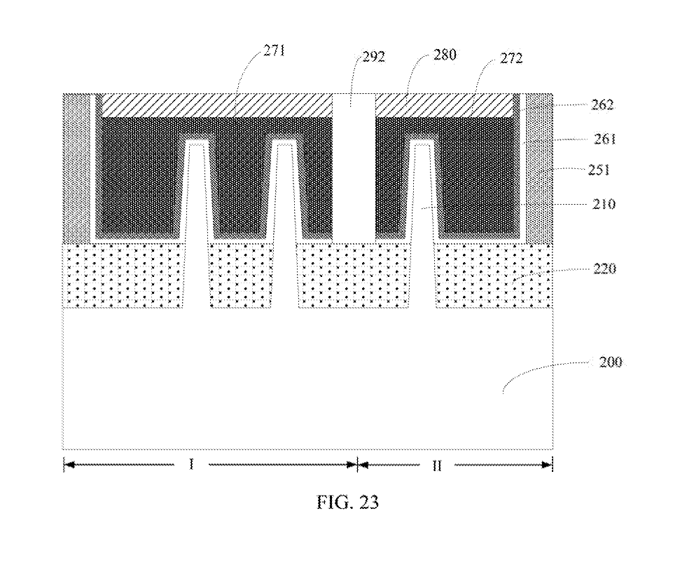

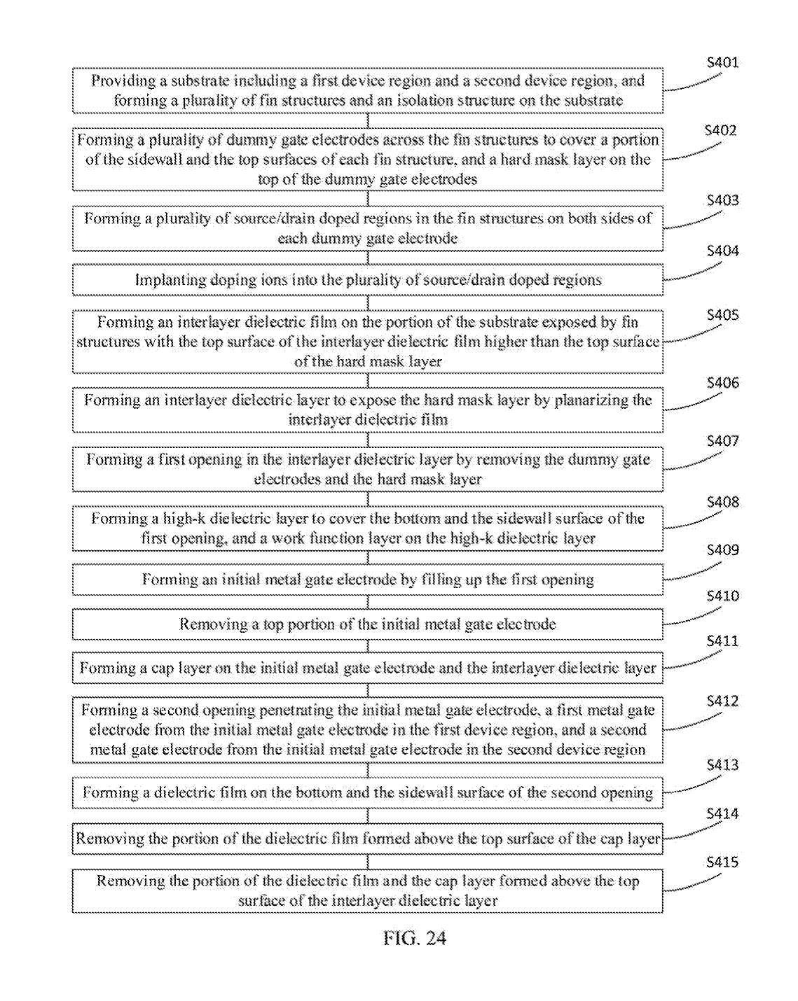

Returning to FIG. 24, a second planarization may be performed on the dielectric film obtained after the first planarization to form a dielectric film by removing the portion of the dielectric film and the cap layer formed above the top surface of the interlayer dielectric layer (S415). FIG. 23 illustrates a schematic cross-section view of a semiconductor structure consistent with some embodiments of the present disclosure along a direction perpendicular to the extending direction of the fin structure 210.

Referring to FIG. 23, a second planarization may be performed on the dielectric film 291 obtained after the first planarization to remove the portion of the dielectric film 291 (referring to FIG. 22) and the cap layer 280 formed above the top surface of the interlayer dielectric layer 251. As such a dielectric layer 292 filling up the second opening 290 (referring to FIG. 20) may be formed from the dielectric film 293.

In one embodiment, the dielectric layer 292 may be made of a low-k dielectric material. The low-k dielectric material may refer to a material with a dielectric constant lower than 3.9. For example, the low-k dielectric material, may be one or more of SiOₓ, SiON, and SiCO.

In one embodiment, the second planarization process performed on the dielectric film 291 may be a CMP process. Using a CMP process to planarize the dielectric film 291 and thus form the dielectric layer 292 may be able to improve the flatness of the top surface of the formed dielectric layer 292.

In one embodiment, forming the dielectric layer 292 by performing a second planarization process after completion of a first planarization process may be able to improve the quality of the dielectric layer. In other embodiments, the dielectric layer may be formed by removing the portion of the dielectric film and the cap layer formed above the top surface of the interlayer dielectric layer through a single planarization process.

Further, the present disclosure also provides a Fin-FET device. FIG. 23 illustrates a schematic cross-section view of an exemplary Fin-FET device consistent with some embodiments of the present disclosure.

Referring to FIG. 23, the Fin-FET device may include a substrate 200. The substrate 200 may include a first device region I and a second device region II. The Fin-FET device may also include a plurality of discrete fin structures 210 and an isolation structure 220 formed on the substrate 200.

The Fin-FET device may also include an interlayer dielectric layer 251 formed on the substrate 200, and a first opening (not labeled) formed in the interlayer dielectric layer 251 to expose a portion of the top and the sidewall surfaces of each fin structure 210. The first opening may be formed by removing a plurality of dummy gate electrodes 230 formed across the plurality of fin structures 210.

Further, the Fin-FET device may include a dielectric layer 292 formed on the isolation structure 220 at the boundary between the first device region I and the second device region II to occupy a portion of the first opening.

Moreover, the Fin-FET device may include a high-k dielectric layer 261 formed on the bottom and the sidewall surfaces of the first opening and a work function layer 262 formed on the high-k dielectric layer 261. In one embodiment, the dielectric layer 292 may divide each of the high-k dielectric layer 261 and the work function layer 262 into two parts, corresponding the first device region I and the second device region II, respectively. In other embodiments, the high-k dielectric layer and the work function layer in the first device may not be separated into two parts by the dielectric layer.

The Fin-FET device may also include a first metal gate electrode 271 formed on the portion of the work function layer 262 in the first device region I, and a second metal gate electrode 272 formed on the portion of the work function layer 262 in the second device region II. The top surfaces of the first metal gate electrode 271 and foe second metal gate electrode 272 may be lower than the top surface of the interlayer dielectric layer 251.

The Fin-FET may include a cap layer 280 formed on the first metal gate electrode 271 and the second metal gate electrode 272. The top surfaces of the cap layer 280, the dielectric layer 292, and the interlayer dielectric layer 252 may be leveled with each other. In addition, the cap layer 280 may be separated from the interlayer dielectric layer 251 by the high-k dielectric layer 261 and the work function layer 262.

In one embodiment, the first metal gate electrode 271 and the second metal gate electrode 272 may be formed from an initial metal gate electrode in the first opening by removing a portion of the initial metal gate electrode at the boundary between the first device region I and the second device region II. During the process to remove the portion of the initial metal gate electrode formed at the boundary between the first device region I and the second device region II, a portion of the high-k dielectric layer 261, the work function layer 262, and the cap layer 280 initially formed at the boundary between the first device region I and the second device region II may also be removed. As such, a second opening (not labeled) may be formed. Moreover, the second opening may be filled up to form the dielectric layer 292.

In one embodiment, along the direction perpendicular to the extending direction of the fin structure 210, the distance from the first metal gate electrode 271 to the second metal gate electrode 272 may be in a range of approximately 50 Å to 100 Å. That is, the width of the dielectric layer 292 along the direction perpendicular to the extending direction of the fin structure 210 may be in a range of approximately 50 Å to 100 Å.

According to the disclosed Fin-FET device, the initial metal gate electrode may be formed by filling up the first opening. Because the first opening may be easily filled up, the initial metal gate electrode may sufficiently fill up the first opening such that the quality of the initial metal gate electrode may be improved. Further, the first metal gate electrode and the second metal gate electrode may be formed by patterning the initial metal gate electrode. Because the initial metal gate electrode may have desired quality, the quality of the first metal gate electrode and the second metal gate electrode may also be improved. Therefore, the electrical performance of the Fin-FET device may be improved.

Compared to conventional Fin-FET device and fabrication methods, the disclosed Fin-FET devices and fabrication methods may demonstrate several advantages.

According to the disclosed Fin-FET devices and fabrication methods, the second opening may be formed after the initial metal gate electrode is formed. Because the first opening is formed by removing the plurality of dummy gate electrodes, the distance from the sidewall surface of the first opening to the adjacent fin structure is relatively large. Therefore, the aspect ratio of the first opening may be relatively large, and the first opening may be easily filled up. As such, during the process to form the initial metal gate electrode, the initial metal gate electrode may be able to sufficiently fill up the first opening, and thus formation of gaps or pin-holes may be avoided. As a result, the quality of the initial metal gate electrode may be improved. Moreover, after forming the initial metal gate electrode, the second opening as wall as the first metal gate electrode and the second metal gate electrode may then be formed from the initial metal gate electrode. Because the quality of the initial metal gate electrode is desired, the quality of the first metal gate electrode and the second metal gate electrode may also be improved. As such, the electrical performance of the Fin-FET device may be improved.

Moreover, along the direction perpendicular to the extending direction of the fin structure, the width of the second opening may be in a range of approximately 50 Å to 100Å. When the width of the second opening is too large, the semiconductor process materials may be wasted. When the width of the second opening is too small, the semiconductor fabrication process may be more difficult, and the connection between the first metal gate electrode and the second metal gate electrode may not be completely cut off.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fabricating a fin field-effect transistor (Fin-FET) device, comprising:
forming a plurality of discrete fin structures on a substrate, wherein the substrate includes a first device region and a second device region;
forming a plurality of dummy gate electrodes across the fin structures to cover a portion of top and sidewall surfaces of each fin structure;
forming an interlayer dielectric layer on a portion of the fin structures exposed by the dummy gate electrodes, wherein the interlayer dielectric layer exposes the dummy gate electrodes;
forming a first opening in the interlayer dielectric layer by removing each dummy gate electrode;
forming an initial metal gate electrode to fill up the first opening and on the substrate between adjacent fin structures; and
forming a second opening through the initial metal gate electrode and on the substrate, wherein;
a portion of the initial metal gate electrode formed in the first device region is a first metal gate electrode, and a portion of the initial metal gate electrode formed in the second device region is a second metal gate electrode, and
the second opening separates the first metal gate electrode in the first device region from the second metal gate electrode in the second device region.

2. The method for fabricating the Fin-FET device according to claim 1, wherein:
along a direction perpendicular to an extending direction of the fin structures, a width of the second opening is in a range of approximately 50 Å to 100 Å.

3. The method for fabricating the Fin-FET device according to claim 2, wherein:
the second opening is formed by a dry etching process.

4. The method for fabricating the Fin-FET device according to claim 3, wherein parameters used in the dry-etching process include:
an etching gas containing a mixture of CF₄, SF₆, Cl₂, and O₂;
a flowrate of CF₄ in a range of approximately 10 sccm to 500 sccm;
a flowrate of SF₆ in a range of approximately 20 sccm and 300 sccm;
a flowrate of Cl₂ in a range of approximately 6 sccm to 120 sccm;
a flow rate of O₂ in a range of approximately 1 sccm to 90 sccm;
a process pressure in a range of approximately 1 mTorr to 350 mTorr; and
a process power in a range of approximately 100 W to 500 W.

5. The method for fabricating the Fin-FET device according to claim 1, after forming the first opening and prior to forming the initial metal gate electrode, further including:
forming a high-k dielectric layer on the interlayer dielectric layer, and on bottom and sidewall surfaces of the first opening; and
forming a work function layer on the high-k dielectric layer.

6. The method for fabricating the Fin-FET device according to claim 1, prior to forming the second opening, further including:
forming a cap layer on the initial metal gate electrode.

7. The method for fabricating the Fin-FET device according to claim 6, wherein:
the cap layer is made of one or more of SiN₈, SiCN, SiBN, SiCON, SiCN, and amorphous carbon.

8. The method for fabricating the Fin-FET device according to claim 1, after forming the second opening, further including:
forming a dielectric layer to fill up the second opening.

9. The method for fabricating the Fin-FET device according to claim 8, wherein:
the dielectric layer is made of a low-k dielectric material.

10. The method for fabricating the Fin-FET device according to claim 9, wherein:
the dielectric layer is made of one or more of SiOₓ, SiNₓ, and SiON.

11. The method for fabricating the Fin-FET device according to claim 10, wherein:
the dielectric layer is formed by a fluid chemical vapor deposition (CVD) process.

12. The method for fabricating the Fin-FET device according to claim 1, prior to forming the plurality of dummy gate electrodes, further including:
forming an isolation structure on the substrate between neighboring fin structures, wherein:
the isolation structure covers a portion of the sidewall surfaces of each fin structure; and
a top surface of the isolation structure is lower than the top surfaces of the fin structures.

13. A Fin-FET device, comprising:
a substrate including a first device region and a second device region;
a plurality of discrete fin structures formed on the substrate;
an initial metal gate electrode formed across the plurality of fin structure and covering a portion of top and sidewall surfaces of each fin structure in the first and second device regions; and
an interlayer dielectric layer formed on a portion of the fin structures exposed by the initial metal gate electrode, wherein the initial metal gate electrode contains an opening between adjacent fin structures in the first and second device regions.

14. The Fin-FET device according to claim 13, wherein:
along a direction perpendicular to an extending direction of the fin structures, a width of the initial metal gate electrode on each fin structure is in a range of approximately 50 Å to 100 Å.

15. The Fin-FET device according to claim 13, wherein:
a portion of the initial metal gate electrode formed in the first device region is a first metal gate electrode, and
a portion of the initial metal gate electrode formed in the second device region is a second metal gate electrode,
wherein the opening separates the first metal gate electrode in the first device region from the second metal gate electrode in the second device region.

16. The Fin-FET device according to claim 13, further including:
a high-k dielectric layer formed under the initial metal gate electrode and on the fin structure; and
a work function layer formed on the high-k dielectric layer.

17. The Fin-FET device according to claim 13, further including:
a cap layer formed on the initial metal gate electrode, wherein the cap layer is made of one or more of SiNₓ, SiCN, SiBN, SiCON, SiCN, and amorphous carbon.

18. The Fin-FET device according to claim 13, further including:
a dielectric layer filling up the opening.

19. The Fin-FET device according to claim 18, wherein:
the dielectric layer is made of one or more of SiOₓ, SiNₓ, and SiON.

20. The Fin-FET device according to claim 13, further including:
an isolation structure formed on the substrate between neighboring fin structures, wherein:
the isolation structure covers a portion of the sidewall surfaces of each fin structure; and
a top surface of the isolation structure is lower than the top surfaces of the fin structures.
